(19) United States
(12) Patent Application Publication
(10) Pub. No.: US 2026/0009844 A1
(43) Pub. Date: Jan. 8, 2026

(54) CHIP FOR PERFORMING CONTACTLESS CHIP TEST AND METHOD FOR PERFORMING CONTACTLESS CHIP TEST ON INPUT/OUTPUT DRIVER

(71) Applicant: MEDIATEK INC., Hsinchu City (TW)

(72) Inventors: Xiang Lin, Hsinchu City (TW); Ching-Wen Hsieh, Hsinchu City (TW); Han-Jung Huang, Hsinchu City (TW); Jui-Hsing Tseng, Hsinchu City (TW); Ying-Yu Hsu, Hsinchu City (TW)

(73) Assignee: MEDIATEK INC., Hsinchu City (TW)

(21) Appl. No.: 19/180,162

(22) Filed: Apr. 16, 2025

Related U.S. Application Data
(60) Provisional application No. 63/667,718, filed on Jul. 4, 2024.

(51) Int. Cl. G01R 31/303; G01R 31/28

(52) U.S. Cl. CPC G01R 31/303; G01R 31/2856

(57) ABSTRACT

A chip for performing a contactless chip test and a method for performing the contactless chip test on an input/output (IO) driver are provided. The chip includes the IO driver, a receiver and a processor, wherein the IO driver and the receiver are coupled to an IO pad, and the processor is coupled to the IO driver and the receiver. The IO driver drives an IO voltage on the IO pad, and the receiver receives the IO voltage from the IO pad, wherein the receiver includes a reference voltage generator and a comparator, the comparator is coupled to the reference voltage generator. The reference voltage generator provides a reference voltage, and the comparator compares the IO voltage with the reference voltage in order to generate a comparison result. The processor determines whether the IO driver passes the contactless chip test according to the comparison result.

### CROSS REFERENCE TO RELATED APPLICATIONS

This application claims the benefit of U.S. Provisional Application No. 63/667,718, filed on Jul. 4, 2024. The content of the application is incorporated herein by reference.

### BACKGROUND

The present disclosure is related to chip test, and more particularly, to a chip for performing a contactless chip test and a method for performing the contactless chip test on an input/output (IO) driver.

A chip probe (CP) test of related art typically uses a chip probe pad to contact with a direct channel connected to an automatic test equipment (ATE) to enhance test coverage. This method significantly increases a capacitance load of a chip to be tested due to the chip probe pad, thereby limiting IO speed and negatively affecting IO performance. More particularly, with high speed operations, degradation of the IO performance can be more severe.

Thus, there is a need for a novel architecture and an associated method, which can solve the problem of using the chip probe pad connected to the ATE for the CP test.

### SUMMARY

An objective of the present disclosure is to provide a chip for performing a contactless chip test and a method for performing the contactless chip test on an input/output (IO) driver, in order to perform a contactless chip test without using an automatic test equipment (ATE), thereby enhancing IO operating speed and performance.

At least one embodiment of the present disclosure provides a chip for performing a contactless chip test. The chip comprises an IO driver, a receiver and a processor, where the IO driver and the receiver are coupled to an IO pad (e.g. a micro-bump PAD), and the processor is coupled to the IO driver and the receiver. The IO driver is configured to drive an IO voltage on the IO pad, and the receiver is configured to receive the IO voltage from the IO pad, where the receiver comprises a reference voltage generator and a comparator, and the comparator is coupled to the reference voltage generator. The reference voltage generator is configured to provide a reference voltage, and the comparator is configured to compare the IO voltage with the reference voltage in order to generate a comparison result. The processor is configured to determine whether the IO driver passes the contactless chip test according to the comparison result.

At least one embodiment of the present disclosure provides a method for performing a contactless chip test on an IO driver. The method is applicable to a chip, where the chip comprises the IO driver, a receiver and a processor. The method comprises: utilizing the IO driver to drive an IO voltage on an IO pad; utilizing a receiver to receive the IO voltage from the IO pad; utilizing a reference voltage generator of the receiver to provide a reference voltage; utilizing a comparator of the receiver to compare the IO voltage with the reference voltage in order to generate a comparison result; and utilizing a processor to determine whether the IO driver passes the contactless chip test according to the comparison result.

The chip and the method provided by the embodiments of the present disclosure can execute the contactless chip test (e.g. a leakage test or a voltage level test) without using the ATE. As the IO pad is not contacted by external equipment(s), a capacitance load on the IO pad will not be significantly increased. In addition, the present disclosure will not significantly increase additional costs. Thus, the present disclosure can solve the problem of the related art without introducing any side effect or in a way that is less likely to introduce side effects.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a chip according to an embodiment of the present disclosure.

FIG. 2 is a diagram illustrating a working flow of a method for performing a contactless chip test on an input/output (IO) driver according to an embodiment of the present disclosure.

FIG. 3 is a diagram illustrating a working flow of performing a leakage test on a pull down driver shown in FIG. 1 according to an embodiment of the present disclosure.

FIG. 4 is a diagram illustrating a working flow of performing a leakage test on a pull up driver shown in FIG. 1 according to an embodiment of the present disclosure.

FIG. 5 is a control scheme of scanning a reference voltage in a voltage level test according to an embodiment of the present disclosure.

FIG. 6 is a diagram illustrating a working flow of performing a voltage level test in a first mode of an IO driver according to an embodiment of the present disclosure.

FIG. 7 is a diagram illustrating a working flow of performing a voltage level test in a second mode of an IO driver according to an embodiment of the present disclosure.

FIG. 8 is a diagram illustrating a working flow of performing a voltage level test in a third mode of an IO driver according to an embodiment of the present disclosure.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”.

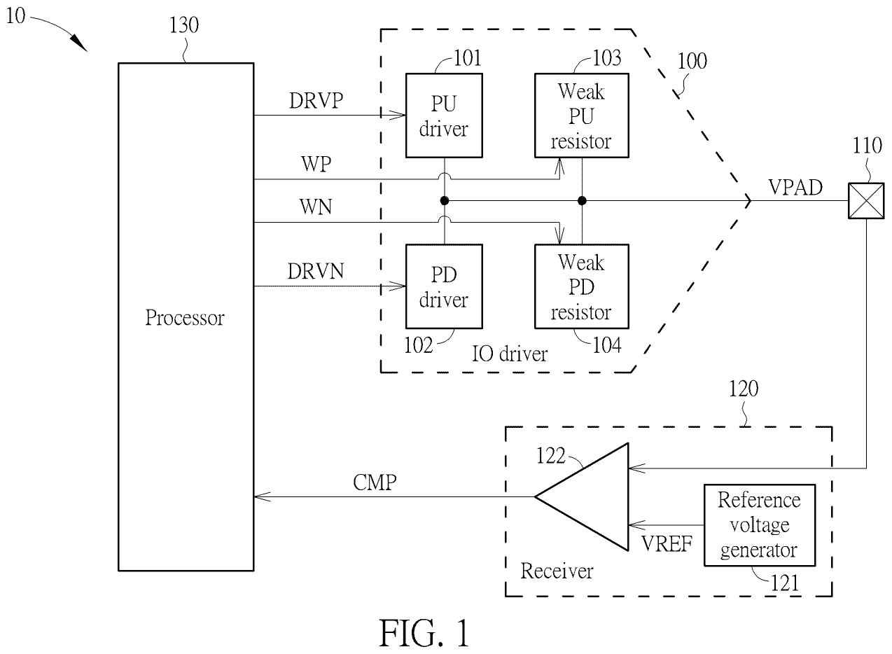

FIG. 1 is a diagram illustrating a chip 10 for performing a contactless chip test according to an embodiment of the present disclosure. In comparison with a chip probe (CP) test of the related art, the contactless chip test of the present disclosure can be performed without utilizing any external test equipment such as an automatic test equipment (ATE). As shown in FIG. 1, the chip 10 (which may be included in an electronic device) comprises an IO driver 100, an IO pad 110, a receiver 120 and a processor 130. The IO driver 100 and the receiver 120 are coupled to the IO pad 110 (e.g. an input of the receiver 120 is coupled to an output of the IO driver 100 via the IO pad 110), and the processor 130 is coupled to the IO driver 100 and the receiver 120 (e.g. coupled to an input of the IO driver 100 and an output of the receiver 120). The IO driver 100 is configured to drive an IO voltage VPAD on the IO pad 110, and the receiver 120 is configured to receive the IO voltage VPAD from the IO pad 110. The receiver 120 comprises a reference voltage generator 121 and a comparator (e.g. an input buffer) 122, and the comparator 122 is coupled to the reference voltage generator 121. In particular, a first input of the comparator 122 is coupled to the IO pad 110, and a second input of the comparator 122 is coupled to the reference voltage generator 121. The reference voltage generator 121 is configured to provide a reference voltage VREF, and the comparator 122 is configured to compare the IO voltage VPAD with the reference voltage VREF in order to generate a comparison result CMP. The processor 130 is configured to determine whether the IO driver 100 passes the contactless chip test according to the comparison result CMP. In this embodiment, the IO pad 110 may be a micro-bump pad, which has a smaller area and a smaller capacitance load in comparison with a chip probe pad (which is utilized for physically contacting with the external test equipment such as the ATE).

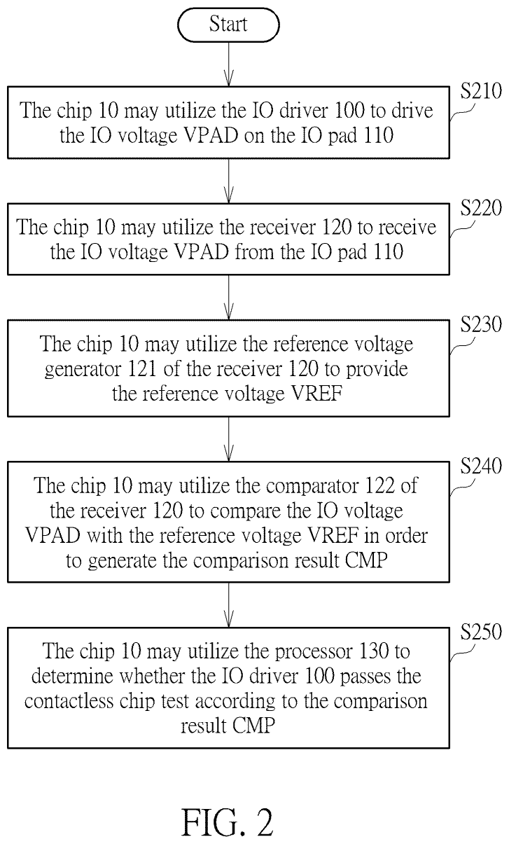

FIG. 2 is a diagram illustrating a working flow of a method for performing the contactless chip test on the IO driver 100 according to an embodiment of the present disclosure, where the method is applicable to the chip 10 (which comprises the IO driver 100, the receiver 120 and the processor 130). It should be noted that the working flow shown in FIG. 2 is for illustrative purposes only, and is not meant to be a limitation of the present disclosure. For example, one or more steps may be added, deleted or modified in the working flow shown in FIG. 2. In addition, if a same result can be obtained, these steps do not have to be executed in the exact order shown in FIG. 2.

In Step S210, the chip 10 may utilize the IO driver 100 to drive the IO voltage VPAD on the IO pad 110.

In Step S220, the chip 10 may utilize the receiver 120 to receive the IO voltage VPAD from the IO pad 110.

In Step S230, the chip 10 may utilize the reference voltage generator 121 of the receiver 120 to provide the reference voltage VREF.

In Step S240, the chip 10 may utilize the comparator 122 of the receiver 120 to compare the IO voltage VPAD with the reference voltage VREF in order to generate the comparison result CMP.

In Step S250, the chip 10 may utilize the processor 130 to determine whether the IO driver 100 passes the contactless chip test according to the comparison result CMP.

As shown in FIG. 1, the IO driver 100 may comprise a pull up (PU) driver 101 and a pull down (PD) driver 102, where the PU driver 101 and the PD driver 102 are coupled to the IO pad 110. The PU driver 101 is configured to pull up the IO voltage VPAD, and the PD driver 102 is configured to pull down the IO voltage VPAD, where the processor 130 is configured to determine whether each of the PU driver 101 and the PD driver 102 passes the contactless chip test according to the comparison result CMP.

In this embodiment, the contactless chip test may comprise a leakage test and a voltage level test. In order to perform the leakage test, the IO driver 100 may further comprise an auxiliary PU resistor (e.g. a weak PU resistor 103) and an auxiliary PD resistor (e.g. a weak PD resistor 104), where the weak PU resistor 103 and the weak PD resistor 104 are coupled to the IO pad 110. The weak PU resistor 103 is configured to pull up the IO voltage VPAD, and the weak PD resistor 104 is configured to pull down the IO voltage VPAD. For example, when the weak PU resistor 103 is turned on, the weak PU resistor 103 provides a PU current path in order to pull up the IO voltage VPAD with a weak PU current (which is weaker than a PU current of the PU driver 101), and when the weak PU resistor 103 is turned off, the weak PU resistor 103 is disconnected from the IO pad 110. When the weak PD resistor 104 is turned on, the weak PD resistor 104 provides a PD current path in order to pull down the IO voltage VPAD with a weak PD current (which is weaker than a PD current of the PD driver 102), and when the weak PD resistor 104 is turned off, the weak PD resistor 104 is disconnected from the IO pad 110. In this embodiment, the processor 130 may transmit control signals DRVP, DRVN, WP and WN to the PU driver 101, the PD driver 102, the weak PU resistor 103 and the weak PD resistor 104, respectively, in order to control whether to turn on the PU driver 101, the PD driver 102, the weak PU resistor 103 and/or the weak PD resistor 104. In addition, the processor 130 may turn off the PU driver 101 (e.g. with the control signal DRVP) and the PD driver 102 (e.g. with the control signal DRVN) and turns on either the auxiliary PU resistor 103 (with the control signal WP (or presented as “PULL_UP”) or the auxiliary PD resistor 104 (with the control signal WN (or presented as “PULL_DN”), in order to perform the leakage test on the IO driver 100.

In detail, when performing the leakage test on the PU driver 101 within the IO driver 100, the processor 130 may turn on the weak PD resistor 104 and turn off the weak PU resistor 103. As the PU driver 101 and the PD driver 102 are turned off, the IO voltage VPAD is expected to be slightly pulled down by the weak PD resistor 104 if there is no leakage from the PU driver 101. The comparator may compare the IO voltage VPAD with a first level (e.g. a reference level VL) of the reference voltage VREF in order to generate a first comparison result, and the processor 130 may determine whether the PU driver 101 passes the leakage test according to the first comparison result (e.g. determining whether the IO voltage VPAD is pulled down to a sufficiently low level). In addition, when performing the leakage test on the PD driver 102, the processor 130 may turn on the weak PU resistor 103 and may turn off the weak PD resistor 104. As the PU driver 101 and the PD driver 102 are turned off, the IO voltage VPAD is expected to be slightly pulled up by the weak PU resistor 103 if there is no leakage from the PD driver 102. The comparator may compare the IO voltage VPAD with a second level (e.g. a reference level VH) of the reference voltage VREF in order to generate a second comparison result, and the processor 130 may determine whether the PD driver 102 passes the leakage test according to the second comparison result (e.g. determining whether the IO voltage VPAD is pulled up to a sufficiently high level).

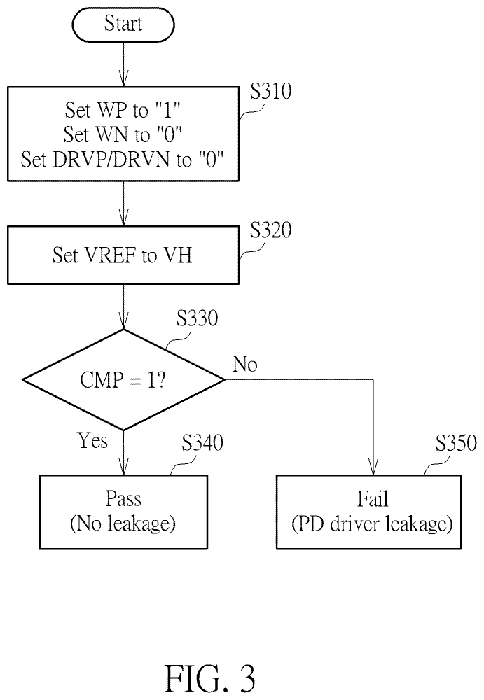

FIG. 3 is a diagram illustrating a working flow of performing the leakage test on the PD driver 102 shown in FIG. 1 according to an embodiment of the present disclosure. It should be noted that the working flow shown in FIG. 3 is for illustrative purposes only, and is not meant to be a limitation of the present disclosure. For example, one or more steps may be added, deleted or modified in the working flow shown in FIG. 3. In addition, if a same result can be obtained, these steps do not have to be executed in the exact order shown in FIG. 3.

In Step S310, the processor 130 may set the control signal WP to a first logic value such as a logic value “1” in order to turn on the weak PU resistor 103, and set the control signal WN to a second logic value such as a logic value “0” in order to turn off the weak PD resistor 104, where the processor sets both the control signals DRVP and DRVN to the logic value “0” in order to turn off both the PU driver 101 and the PD driver 102.

In Step S320, the reference generator 121 may set the reference voltage VREF to the reference level VH.

In Step S330, the comparator 122 may compare the IO voltage VPAD with the reference level VH to generate the second comparison result (e.g. the comparison result CMP generated in the leakage test of the PD driver 102), and the processor 130 may determine whether the IO voltage VPAD is greater than the reference level VH according to the second comparison result (e.g. determining whether the comparison result CMP shows the logic value “1”). If the determination result shows “Yes”, which means the second comparison result indicates that the IO voltage VPAD is greater than the reference level VH (e.g. the comparison result CMP shows the logic value “1”), the working flow proceeds with Step S340. If the determination result shows “No”, which means the second comparison result indicates that the IO voltage VPAD is not greater than the reference level VH (e.g. the comparison result CMP does not show the logic value “1”), the working flow proceeds with Step S350.

In Step S340, the processor 130 may determine that the PD driver 102 passes the leakage test (e.g. determining that there is no leakage from the PD driver 102).

In Step S350, the processor 130 may determine that the PD driver 102 fails to pass the leakage test (e.g. determining that there is leakage from the PD driver 102, which pulls down the IO voltage VPAD, therefore making the IO voltage VPAD less than the reference level VH).

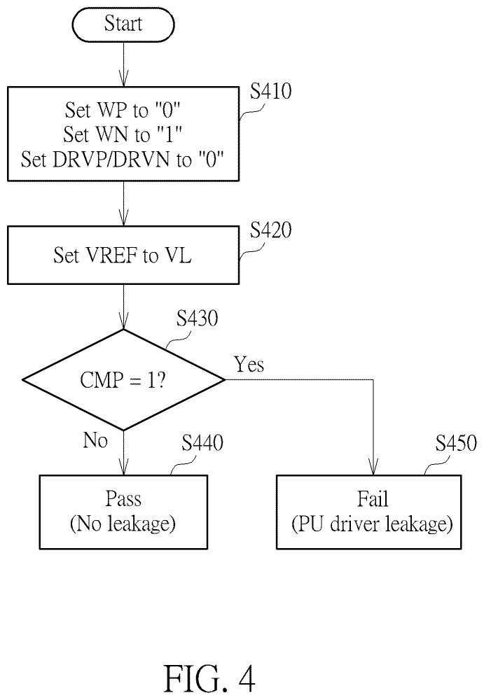

FIG. 4 is a diagram illustrating a working flow of performing the leakage test on the PU driver 101 shown in FIG. 1 according to an embodiment of the present disclosure. It should be noted that the working flow shown in FIG. 4 is for illustrative purposes only, and is not meant to be a limitation of the present disclosure. For example, one or more steps may be added, deleted or modified in the working flow shown in FIG. 4. In addition, if a same result can be obtained, these steps do not have to be executed in the exact order shown in FIG. 4.

In Step S410, the processor 130 may set the control signal WP to the logic value “0” in order to turn off the weak PU resistor 103, and set the control signal WN to the logic value “1” in order to turn on the weak PD resistor 104, where the processor sets both the control signals DRVP and DRVN to the logic value “0” in order to turn off both the PU driver 101 and the PD driver 102.

In Step S420, the reference generator 121 may set the reference voltage VREF to the reference level VL.

In Step S430, the comparator 122 may compare the IO voltage VPAD with the reference level VL to generate the first comparison result (e.g. the comparison result CMP generated in the leakage test of the PU driver 101), and the processor 130 may determine whether the IO voltage VPAD is greater than the reference level VL according to the first comparison result (e.g. determining whether the comparison result CMP shows the logic value “1”). If the determination result shows “Yes”, which means the first comparison result indicates that the IO voltage VPAD is greater than the reference level VL (e.g. the comparison result CMP shows the logic value “1”), the working flow proceeds with Step S450. If the determination result shows “No”, which means the first comparison result indicates that the IO voltage VPAD is not greater than the reference level VL (e.g. the comparison result CMP does not show the logic value “1”), the working flow proceeds with Step S440.

In Step S440, the processor 130 may determine that the PU driver 101 passes the leakage test (e.g. determining that there is no leakage from the PU driver 101).

In Step S450, the processor 130 may determine that the PU driver 101 fails to pass the leakage test (e.g. determining that there is leakage from the PD driver 102, which pulls up the IO voltage VPAD, therefore making the IO voltage VPAD greater than the reference level VL).

In the leakage test, with proper enablement control of each of the PU driver 101, the PD driver 102, the weak PU resistor 103 and the weak PD resistor 104, the IO voltage VPAD may be pulled to a corresponding level in response to whether any leakage path exist in the IO driver 100, and the processor 130 may determine whether any leakage path exist in the IO driver according to the comparison result CMP, which is generated according to the IO voltage VPAD by the receiver 120 (more particularly, the comparator 122 therein).

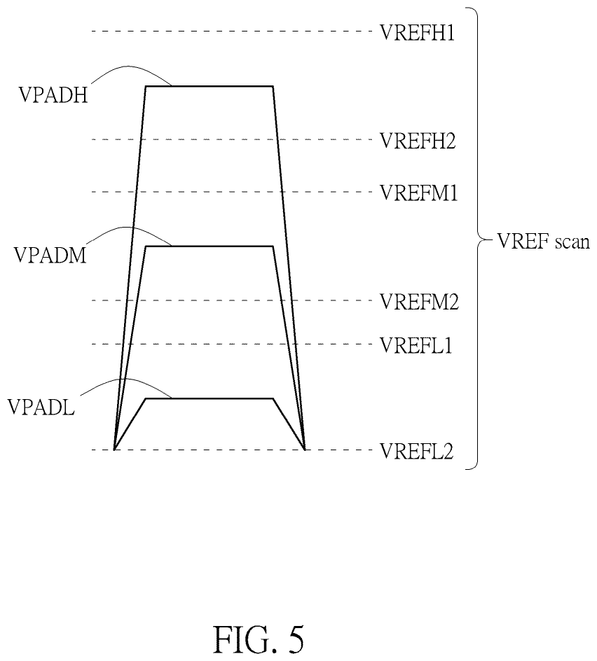

FIG. 5 is a control scheme of scanning the reference voltage VREF in the voltage level test according to an embodiment of the present disclosure. In this embodiment, the PU driver 101 may have multiple PU driving strengths, and the PD driver 102 may have multiple PD driving strengths, where multiple modes of the IO driver 100 respectively correspond to different combinations of the multiple PU driving strengths and the multiple PD driving strengths. For example, the multiple PU driving strengths may comprise a strong PU driving strength, a medium PU driving strength and a weak PU driving strength, and the multiple PD driving strengths may comprise a strong PD driving strength, a medium PD driving strength and a weak PD driving strength. In a first mode of the IO driver 100, the PU driver 101 is set to have the strong PU driving strength, and the PD driver 102 is set to have the weak PD driving strength. In a second mode of the IO driver 100, the PU driver 101 is set to have the medium PU driving strength, and the PD driver 102 is set to have the medium PD driving strength. In a third mode of the IO driver 100, the PU driver 101 is set to have the weak PU driving strength, and the PD driver 102 is set to have the strong PD driving strength. In this embodiment, the processor 130 may sets the IO driver 100 to the multiple modes (e.g. the first mode, the second mode and the third mode) by turns, in order to perform the voltage level test on the IO driver. It should be noted that the weak PU resistor 103 and the weak PD resistor 104 can be omitted (e.g. disabled or turned off) in the voltage level test.

In order to perform the voltage level test, the processor 130 may control strengths of the PU driver 101 and the PD driver 102 with the control signals DRVP and DRVN, where the IO voltage VPAD may be pulled to different levels in response to different settings of the strengths of the PU driver 101 and the PD driver 102. More particularly, the processor 130 may determine whether the IO voltage VPAD falls in a corresponding range under each of the multiple modes of the IO driver 100 according to the comparison result CMP, in order to determine whether the IO driver 100 passes the voltage level test. For example, when the IO driver 100 is set to operate in the first mode (e.g. setting the PU driver 101 to have the strong PU driving strength and setting the PD driver 102 to have the weak PD driving strength), the IO voltage VPAD is expected to be pulled to a first level VPADH which falls in a high range (e.g. between levels VREFH1 and VREFH2). When the IO driver 100 is set to operate in the second mode (e.g. setting the PU driver 101 to have the medium PU driving strength and setting the PD driver 102 to have the medium PD driving strength), the IO voltage VPAD is expected to be pulled to a second level VPADM which falls in a medium range (e.g. between levels VREFM1 and VREFM2). When the IO driver 100 is set to operate in the third mode (e.g. setting the PU driver 101 to have the weak PU driving strength and setting the PD driver 102 to have the strong PD driving strength), the IO voltage VPAD is expected to be pulled to a third level VPADL which falls in a low range (e.g. between levels VREFM1 and VREFM2). Thus, when the comparison result CMP indicates that the IO voltage VPAD falls in the corresponding range under each of the multiple modes of the IO driver 100 (e.g. indicating that the IO voltage VPAD generated under the first mode falls in the high range, the IO voltage VPAD generated under the second mode falls in the medium range, and the IO voltage VPAD generated under the third mode falls in the low range), the processor 130 may determine that the IO driver 100 passes the voltage level test. When the comparison result CMP indicates that the IO voltage VPAD falls outside the corresponding range under any of the multiple modes of the IO driver 100 (e.g. indicating that the IO voltage VPAD generated under the first mode falls outside the high range, the IO voltage VPAD generated under the second mode falls outside the medium range, or the IO voltage VPAD generated under the third mode falls outside the low range), the processor 130 may determine that the IO driver 100 fails to pass the voltage level test.

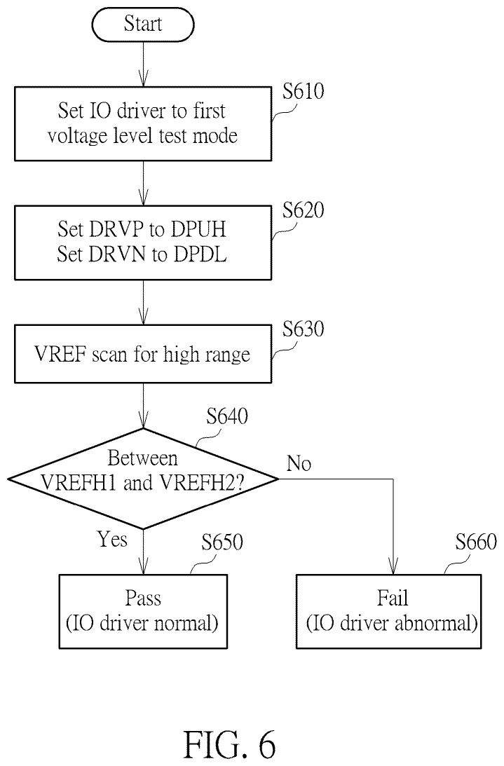

FIG. 6 is a diagram illustrating a working flow of performing the voltage level test in the first mode of the IO driver 100 (e.g. setting the PU driver 101 to have the strong PU driving strength and setting the PD driver 102 to have the weak PD driving strength) according to an embodiment of the present disclosure. It should be noted that the working flow shown in FIG. 6 is for illustrative purposes only, and is not meant to be a limitation of the present disclosure. For example, one or more steps may be added, deleted or modified in the working flow shown in FIG. 6. In addition, if a same result can be obtained, these steps do not have to be executed in the exact order shown in FIG. 6.

In Step S610, the processor 130 may set the IO driver 100 to operate in the first mode for the voltage level test (referred to as a first voltage level test mode in FIG. 6 for brevity).

In Step S620, the processor 130 may set the control signal DRVP to a strong mode value DPUH to make the PU driver 101 to have the strong PU driving strength, and set the control signal DRVN to a weak mode value DPDL to make the PD driver 102 to have the weak PD driving strength.

In Step S630, the reference voltage generator 121 may scan the reference voltage VREF for the high range (e.g. setting the reference voltage VREF to the levels VREFH1 and VREFH2 sequentially), and the comparator 122 may determine whether the IO voltage VPAD is less than the level VREFH1 and greater than the level VREFH2, to thereby generate the comparison result CMP.

In Step S640, the processor 130 may determine whether the IO voltage VPAD generated under the first mode falls in the high range between the levels VREFH1 and VREFH2. For example, the processor 130 may determine whether the comparison result CMP shows the logic value “0” (which means the IO voltage VPAD is not greater than the level VREFH1) in response to the reference voltage VREF being set to the level VREFH1 and the comparison result CMP shows the logic value “1” (which means the IO voltage VPAD is greater than the level VREFH2) in response to the reference voltage VREF being set to the level VREFH2. If the determination result shows “Yes”, which means the IO voltage VPAD generated under the first mode falls in the high range between the levels VREFH1 and VREFH2, the working flow proceeds with Step S650. If the determination result shows “No”, which means the IO voltage VPAD generated under the first mode falls outside the high range between the levels VREFH1 and VREFH2, the working flow proceeds with Step S660.

In Step S650, the processor 130 may determine that the IO driver 100 passes the voltage level test in the first mode, and operations of the IO driver 100 is determined to be normal in the first mode.

In Step S660, the processor 130 may determine that the IO driver 100 fails to pass the voltage level test, and the operations of the IO driver 100 is determined to be abnormal.

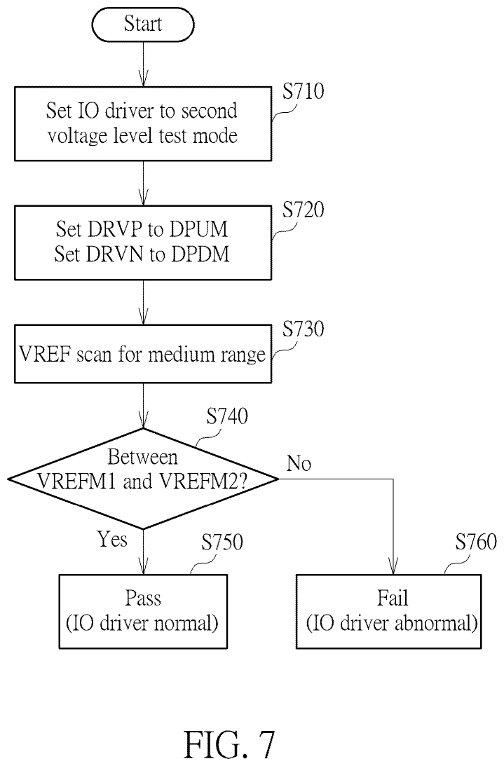

FIG. 7 is a diagram illustrating a working flow of performing the voltage level test in the second mode of the IO driver 100 (e.g. setting the PU driver 101 to have the medium PU driving strength and setting the PD driver 102 to have the medium PD driving strength) according to an embodiment of the present disclosure. It should be noted that the working flow shown in FIG. 7 is for illustrative purposes only, and is not meant to be a limitation of the present disclosure. For example, one or more steps may be added, deleted or modified in the working flow shown in FIG. 7. In addition, if a same result can be obtained, these steps do not have to be executed in the exact order shown in FIG. 7.

In Step S710, the processor 130 may set the IO driver 100 to operate in the second mode for the voltage level test (referred to as a second voltage level test mode in FIG. 7 for brevity).

In Step S720, the processor 130 may set the control signal DRVP to a medium mode value DPUM to make the PU driver 101 to have the medium PU driving strength, and set the control signal DRVN to a medium mode value DPDM to make the PD driver 102 to have the medium PD driving strength.

In Step S730, the reference voltage generator 121 may scan the reference voltage VREF for the medium range (e.g. setting the reference voltage VREF to the levels VREFM1 and VREFM2 sequentially), and the comparator 122 may determine whether the IO voltage VPAD is less than the level VREFM1 and greater than the level VREFM2, to thereby generate the comparison result CMP.

In Step S740, the processor 130 may determine whether the IO voltage VPAD generated under the second mode falls in the medium range between the levels VREFM1 and VREFM2. For example, the processor 130 may determine whether the comparison result CMP shows the logic value “0” (which means the IO voltage VPAD is not greater than the level VREFM1) in response to the reference voltage VREF being set to the level VREFM1 and the comparison result CMP shows the logic value “1” (which means the IO voltage VPAD is greater than the level VREFM2) in response to the reference voltage VREF being set to the level VREFM2. If the determination result shows “Yes”, which means the IO voltage VPAD generated under the second mode falls in the medium range between the levels VREFM1 and VREFM2, the working flow proceeds with Step S750. If the determination result shows “No”, which means the IO voltage VPAD generated under the second mode falls outside the medium range between the levels VREFM1 and VREFM2, the working flow proceeds with Step S760.

In Step S750, the processor 130 may determine that the IO driver 100 passes the voltage level test in the second mode, and operations of the IO driver 100 is determined to be normal in the second mode.

In Step S760, the processor 130 may determine that the IO driver 100 fails to pass the voltage level test, and the operations of the IO driver 100 is determined to be abnormal.

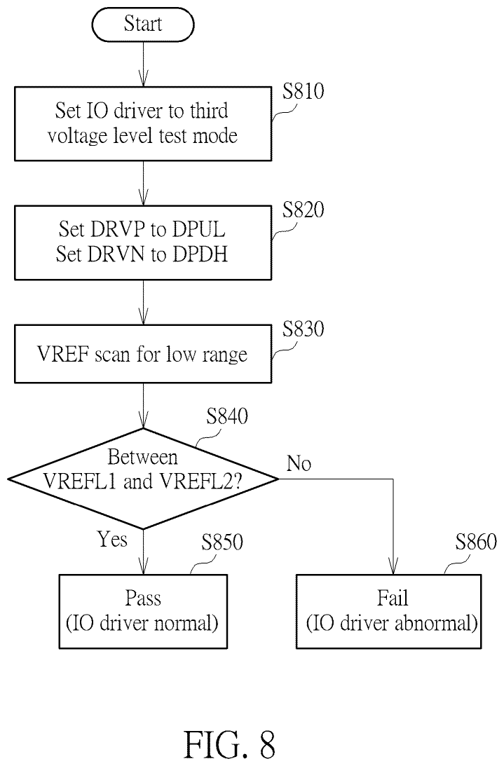

FIG. 8 is a diagram illustrating a working flow of performing the voltage level test in the third mode of the IO driver 100 (e.g. setting the PU driver 101 to have the weak PU driving strength and setting the PD driver 102 to have the strong PD driving strength) according to an embodiment of the present disclosure. It should be noted that the working flow shown in FIG. 8 is for illustrative purposes only, and is not meant to be a limitation of the present disclosure. For example, one or more steps may be added, deleted or modified in the working flow shown in FIG. 8. In addition, if a same result can be obtained, these steps do not have to be executed in the exact order shown in FIG. 8.

In Step S810, the processor 130 may set the IO driver 100 to operate in the third mode for the voltage level test (referred to as a third voltage level test mode in FIG. 8 for brevity).

In Step S820, the processor 130 may set the control signal DRVP to a medium mode value DPUL to make the PU driver 101 to have the weak PU driving strength, and set the control signal DRVN to a strong mode value DPDH to make the PD driver 102 to have the strong PD driving strength.

In Step S830, the reference voltage generator 121 may scan the reference voltage VREF for the low range (e.g. setting the reference voltage VREF to the levels VREFL1 and VREFL2 sequentially), and the comparator 122 may determine whether the IO voltage VPAD is less than the level VREFL1 and greater than the level VREFL2, to thereby generate the comparison result CMP.

In Step S840, the processor 130 may determine whether the IO voltage VPAD generated under the third mode falls in the low range between the levels VREFL1 and VREFL2. For example, the processor 130 may determine whether the comparison result CMP shows the logic value “0” (which means the IO voltage VPAD is not greater than the level VREFL1) in response to the reference voltage VREF being set to the level VREFL1 and the comparison result CMP shows the logic value “1” (which means the IO voltage VPAD is greater than the level VREFL2) in response to the reference voltage VREF being set to the level VREFL2. If the determination result shows “Yes”, which means the IO voltage VPAD generated under the third mode falls in the low range between the levels VREFL1 and VREFL2, the working flow proceeds with Step S850. If the determination result shows “No”, which means the IO voltage VPAD generated under the third mode falls outside the low range between the levels VREFL1 and VREFL2, the working flow proceeds with Step S860.

In Step S850, the processor 130 may determine that the IO driver 100 passes the voltage level test in the third mode, and operations of the IO driver 100 is determined to be normal in the third mode.

In Step S860, the processor 130 may determine that the IO driver 100 fails to pass the voltage level test, and the operations of the IO driver 100 is determined to be abnormal.

In the voltage level test, with scanning of the reference voltage VREF, the processor can determine whether the IO voltage VPAD is pulled to a target range in response to the setting of the strengths of the PU driver 101 and the PD driver 102, in order to confirm whether the strengths of the PU driver 101 and the PD driver 102 in the multiple modes meet target specification (e.g. confirming whether any of the PU driver 101 and the PD driver 102 is too strong or too weak in any of the multiple modes).

To summarize, the chip and the associated method provided by the embodiments of the present disclosure can utilize the receiver 120 to generate a detection result (e.g. the comparison result CMP output from the comparator 122), to allow the processor 130 to determine whether the IO driver 100 passes the leakage test and the voltage level test without using chip probe pad(s) and connecting any external automatic test equipment (ATE). Thus, a capacitance load for the chip 10 (more particularly, for the IO driver 100) will not be significantly increased due to requirement (e.g. the chip probe pad which is utilized for physically contacting with the ATE) of the chip test. Thus, the present invention can prevent performance of the IO driver 100 from being negatively affected due to the chip probe pad, as only the IO pad 110 (e.g. the micro-bump pad) which has a smaller capacitance load is needed. In addition, the embodiments of the present disclosure will not significantly increase additional costs. Thus, the present disclosure can solve the problem of the related art without introducing any side effect or in a way that is less likely to introduce side effects.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A chip for performing a contactless chip test, comprising:
an input/output (IO) driver, coupled to an IO pad, configured to drive an IO voltage on the IO pad;
a receiver, coupled to the IO pad, configured to receive the IO voltage from the IO pad, wherein the receiver comprises:
a reference voltage generator, configured to provide a reference voltage; and
a comparator, coupled to the reference voltage generator, configured to compare the IO voltage with the reference voltage to generate a comparison result; and
a processor, coupled to the IO driver and the receiver, configured to determine whether the IO driver passes the contactless chip test according to the comparison result.

2. The chip of claim 1, wherein the IO driver comprises:
a pull up (PU) driver, coupled to the IO pad, configured to pull up the IO voltage; and
a pull down (PD) driver, coupled to the IO pad, configured to pull down the IO voltage,
wherein the processor is further configured to determine whether each of the PU driver and the PD driver passes the contactless chip test according to the comparison result.

3. The chip of claim 2, wherein the contactless chip test comprises a leakage test, and the IO driver further comprises:
an auxiliary PU resistor, coupled to the IO pad, configured to pull up the IO voltage; and
an auxiliary PD resistor, coupled to the IO pad, configured to pull down the IO voltage,
wherein the processor turns off the PU driver and the PD driver and turns on either the auxiliary PU resistor or the auxiliary PD resistor, to perform the leakage test on the PU driver or the PD driver.

4. The chip of claim 3, wherein:
when performing the leakage test on the PU driver, the processor turns on the auxiliary PD resistor and turns off the auxiliary PU resistor, the comparator compares the IO voltage with a first level of the reference voltage to generate a first comparison result, and the processor determines whether the PU driver passes the leakage test according to the first comparison result; and
when performing the leakage test on the PD driver, the processor turns on the auxiliary PU resistor and turns off the auxiliary PD resistor, the comparator compares the IO voltage with a second level of the reference voltage to generate a second comparison result, and the processor determines whether the PD driver passes the leakage test according to the second comparison result.

5. The chip of claim 4, wherein when the first comparison result indicates that the IO voltage is greater than the first level of the reference voltage, the processor determines that the PU driver fails to pass the leakage test.

6. The chip of claim 4, wherein when the second comparison result indicates that the IO voltage is not greater than the second level of the reference voltage, the processor determines that the PD driver fails to pass the leakage test.

7. The chip of claim 2, wherein the contactless chip test comprises a voltage level test, the PU driver has multiple PU driving strengths, the PD driver has multiple PD driving strengths, multiple modes of the IO driver respectively correspond to different combinations of the multiple PU driving strengths and the multiple PD driving strengths, and the processor sets the IO driver to the multiple modes by turns, in order to perform the voltage level test on the IO driver.

8. The chip of claim 7, wherein the processor is further configured to determine whether the IO voltage falls in a corresponding range under each of the multiple modes of the IO driver according to the comparison result, to determine whether the IO driver passes the voltage level test.

9. The chip of claim 8, wherein when the comparison result indicates that the IO voltage falls in the corresponding range under each of the multiple modes of the IO driver, the processor determines that the IO driver passes the voltage level test.

10. The chip of claim 1, wherein the IO pad is a micro-bump pad.

11. A method for performing a contactless chip test on an input/output (IO) driver, wherein the method is applicable to a chip, the chip comprises the IO driver, a receiver and a processor, and the method comprises:
utilizing the IO driver to drive an IO voltage on a IO pad;
utilizing the receiver to receive the IO voltage from the IO pad;
utilizing a reference voltage generator of the receiver to provide a reference voltage;
utilizing a comparator of the receiver to compare the IO voltage with the reference voltage in order to generate a comparison result; and
utilizing the processor to determine whether the IO driver passes the contactless chip test according to the comparison result.

12. The method of claim 11, wherein the IO driver comprises a pull up (PU) driver and a pull down (PD) driver, the PU driver is configured to pull up the IO voltage, the PD driver is configured to pull down the IO voltage, and utilizing the processor to determine whether the IO driver passes the contactless chip test according to the comparison result comprises:
utilizing the processor to determine whether each of the PU driver and the PD driver passes the contactless chip test according to the comparison result.

13. The method of claim 12, wherein the contactless chip test comprises a leakage test, the IO driver further comprises an auxiliary PU resistor and an auxiliary PD resistor, the auxiliary PU resistor is configured to pull up the IO voltage, the auxiliary PD resistor is configured to pull down the IO voltage, and the method further comprises:
utilizing the processor to turn off the PU driver and the PD driver and turn on either the auxiliary PU resistor or the auxiliary PD resistor, to perform the leakage test on the PU driver or the PD driver.

14. The method of claim 13, wherein utilizing the processor to turn off the PU driver and the PD driver and turn on either the auxiliary PU resistor or the auxiliary PD resistor to perform the leakage test on the IO driver comprises:
utilizing the processor to turn on the auxiliary PD resistor and turn off the auxiliary PU resistor for performing the leakage test on the PU driver, wherein the comparator compares the IO voltage with a first level of the reference voltage to generate a first comparison result, and the processor determines whether the PU driver passes the leakage test according to the first comparison result; and
utilizing the processor to turn on the auxiliary PU resistor and turn off the auxiliary PD resistor for performing the leakage test on the PD driver, wherein the comparator compares the IO voltage with a second level of the reference voltage to generate a second comparison result, and the processor determines whether the PD driver passes the leakage test according to the second comparison result.

15. The method of claim 14, further comprising:
in response to the first comparison result indicating that the IO voltage is greater than the first level of the reference voltage, utilizing the processor to determine that the leakage test fails.

16. The method of claim 14, further comprising:
in response to the second comparison result indicating that the IO voltage is less than the second level of the reference voltage, utilizing the processor to determine that the leakage test fails.

17. The method of claim 12, wherein the contactless chip test comprises a voltage level test, the PU driver has multiple PU driving strengths, the PD driver has multiple PD driving strengths, multiple modes of the IO driver respectively correspond to different combinations of the multiple PU driving strengths and the multiple PD driving strengths, and the method further comprises:
utilizing the processor to set the IO driver to the multiple modes by turns, in order to perform the voltage level test on the IO driver.

18. The method of claim 17, wherein utilizing the processor to determine whether the IO driver passes the contactless chip test according to the comparison result comprises:
utilizing the processor to determine whether the IO voltage falls in a corresponding range under each of the multiple modes of the IO driver according to the comparison result, in order to determine whether the IO driver passes the voltage level test.

19. The method of claim 18, further comprising:
in response to the comparison result indicating that the IO voltage falls in the corresponding range under each of the multiple modes of the IO driver, utilizing the processor to determine that the IO driver passes the voltage level test.

20. The method of claim 11, wherein the IO pad is a micro-bump pad.
